(19) United States
(12) Patent Application Publication
(10) Pub. No.: US 2016/0035993 A1
(43) Pub. Date: Feb. 4, 2016

(54) ORGANIC ELECTROLUMINESCENT DEVICE AND DISPLAY DEVICE

(71) Applicant: BOE TECHNOLOGY GROUP CO., LTD., Beijing (CN)

(72) Inventors: Dongfang YANG, Beijing (CN); Lujiang HUANGFU, Beijing (CN); Pilseok KIM, Beijing (CN)

(21) Appl. No.: 14/422,783

(22) PCT Filed: Apr. 22, 2014
(86) PCT No.: PCT/CN2014/075957

§ 371 Date: Feb. 20, 2015

(30) Foreign Application Priority Data
Dec. 23, 2013 (CN) 201310718937.8

(51) Int. Cl. H01L 51/50; H01L 51/52

(52) U.S. Cl. CPC H01L 51/5012; H01L 51/5262

(57) ABSTRACT

The present invention provides an organic electroluminescent device and a display device. The organic electroluminescent device comprises an anode layer, a cathode layer and an organic function layer provided between the anode layer and the cathode layer, an injection barrier from the anode layer to the organic function layer and an injection barrier from the cathode layer to the organic function layer are both not larger than 1 ev. A light emitting layer comprises a hole carrier transport region at a side of the anode layer, an electron carrier transport region at a side of the cathode layer and a light emitting region provided between the hole carrier transport region and the electron carrier transport region, there is no barrier for the hole carriers from the hole carrier transport region to the light emitting region and for the electron carriers from the electron carrier transport region to the light emitting region.

### CROSS-REFERENCE TO RELATED APPLICATION

This application claims priority to Chinese Patent Application No. 201310718937.8, filed on Dec. 23, 2013, in the Chinese Intellectual Property Office, the disclosure of which is incorporated by reference herein in its entirety.

### FIELD OF THE INVENTION

The present invention relates to the field of display technology, and particularly to an organic electroluminescent device and a display device.

### BACKGROUND OF THE INVENTION

Organic light emitting diode (OLED) is a kind of organic thin film electroluminescent device and has advantages of simple fabricating process, low cost, high luminous efficiency, easy to form a flexible structure, etc. Therefore, the display technology utilizing the organic light emitting diode becomes an important display technology.

As shown in FIG. 1, the organic light emitting diode comprises a cathode layer 2, an anode layer 1 (the reference numbers 1, 2 in the drawings only illustrate high and low of energy level positions of the anode layer and the cathode layer) and an “organic function layer” provided between the cathode layer 2 and the anode layer 1. The “organic function layer” may be a light emitting layer of a single layer structure or may consist of a plurality of different layers. The “organic function layer” comprises at least a light emitting layer (EML) 5, and may further comprise: an electron transport layer (ETL) 4 and an electron injection layer (EIL) 7 which are provided between the light emitting layer 5 and the cathode layer 2; and a hole injection layer (HIL) 6 and a hole transport layer (HTL) 3 which are provided between the light emitting layer 5 and the anode layer 1. Generally, HOMO (highest occupied molecular orbital) energy level position of the electron transport layer 4 is lower than HOMO energy level position of the light emitting layer 5, so as to block transmission of the hole carriers to the cathode layer 2, so that a concentration of the hole carriers at an interface between the electron transport layer 4 and the light emitting layer 5 is very high, and quenching of excitons or carrier pairs is likely to be caused in that region. A patent document with an application number 200910067007.4 discloses an organic light emitting diode structure in which the light emitting layer is doped with a kind of electron carrier transport material, so as to improve injection capability of carriers and reduce aggregation and quenching of exciton, thereby improving efficiency of the organic light emitting diode.

The inventors found that at least the following problem exists in the prior art, the carriers are aggregated at a position of energy level barrier due to a difference of work function between the light emitting layer 5 and the electrode, resulting in quenching of exciton. Therefore, someone reduces the quenching of exciton caused by the aggregation of carriers by using a structure of anode layer 1 with high work function/dual transport carrier light emitting layer 5/electron transport layer 4/cathode layer 2. However, since the material of the light emitting layer 5 has a characteristic of dual transport, electron carriers which are not recombined move towards the anode layer 1, resulting in quenching of carriers at the electrode.

### SUMMARY OF THE INVENTION

To solve the problem existing in the prior art, the technical problem to be solved in the present invention is to provide an organic electroluminescent device, which may improve a luminous efficiency of the organic light emitting device and extend a service life thereof.

To solve the above technical problem, the present invention provides a technical solution of an organic electroluminescent device, comprising an anode layer, a cathode layer and an organic function layer provided between the anode layer and the cathode layer, the organic function layer comprises a light emitting layer, an injection barrier from the anode layer to the organic function layer and an injection barrier from the cathode layer to the organic function layer are both not larger than 1 ev; and the light emitting layer comprises a hole carrier transport region at a side of the anode layer, an electron carrier transport region at a side of the cathode layer, and a light emitting region provided between the hole carrier transport region and the electron carrier transport region, wherein there is no barrier for the hole carriers from the hole carrier transport region to the light emitting region and there is no barrier for the electron carriers from the electron carrier transport region to the light emitting region.

Preferably, the light emitting layer is made of undoped fluorescent organic material consisting of light emitting material and having a hole carrier transport capability, or the light emitting layer is made of organic material doped with fluorescent material and consisting of fluorescent dopant and host material, or the light emitting layer is made of organic material doped with phosphorescent material and consisting of phosphorescent dopant and host material.

Preferably, the light emitting layer is made of undoped fluorescent organic material consisting of light emitting material and having an electron carrier transport capability, or the light emitting layer is made of organic material doped with fluorescent material and consisting of fluorescent dopant and host material, or the light emitting layer is made of organic material doped with phosphorescent material and consisting of phosphorescent dopant and host material.

Preferably, the organic function layer further comprises an electron transport layer provided between the light emitting layer and the cathode layer, a LUMO energy level position of the electron transport layer is higher than that of the light emitting layer by 0˜1 ev, and the light emitting layer has a hole carrier transport capability not lower than an electron carrier transport capability.

Further preferably, a HOMO energy level position of the electron transport layer is lower than that of the light emitting layer by 0˜1 ev.

Further preferably, the organic function layer further comprises an electron blocking layer for blocking non-recombined electron carriers from moving to the anode layer.

Further preferably, a thickness of the electron blocking layer is ranged from 1 nm to 10 nm.

Further preferably, the non-recombined electron carriers are recombined with the hole carriers at a portion of the light emitting layer close to the anode layer through the electron blocking layer.

Preferably, the organic function layer further comprises a hole transport layer provided between the anode layer and the light emitting layer, a HOMO energy level position of the hole transport layer is lower than that of the light emitting layer by 0˜1 ev, and the light emitting layer has an electron carrier transport capability higher than a hole carrier transport capability.

Further preferably, a LUMO energy level position of the hole transport layer is higher than that of the light emitting layer by 0˜1 ev.

Further preferably, the organic function layer further comprises a hole blocking layer for blocking non-recombined hole carriers from moving to the cathode layer.

Further preferably, a thickness of the hole blocking layer is ranged from 1 nm to 10 nm.

Further preferably, the non-recombined hole carriers are recombined with the electron carriers at a portion of the light emitting layer close to the cathode layer through the hole blocking layer.

Preferably, the organic function layer further comprises a hole transport layer provided between the anode layer and the light emitting layer and an electron transport layer provided between the cathode layer and the light emitting layer, a HOMO energy level position of the hole transport layer is lower than that of the light emitting layer by 0˜1 ev, and a LUMO energy level position of the electron transport layer is higher than that of the light emitting layer by 0˜1 ev.

Further preferably, the light emitting layer is made of organic material consisting of light emitting material and having a hole carrier transport capability or made of organic material consisting of light emitting material and having an electron carrier transport capability.

Preferably, the organic function layer further comprises a hole injection layer that is provided between the anode layer and the hole transport layer of the organic electroluminescent device.

Further preferably, the material of the hole injection layer is p-doped hole injection material, the dopant material of which is F4-TCNQ.

Preferably, the organic function layer further comprises an electron injection layer that is provided between the cathode layer and the electron transport layer of the organic electroluminescent device.

Further preferably, the material of the electron injection layer is n-doped electron injection material, the dopant material of which is Ce or Li.

The present invention further provides a display device, comprising the above organic electroluminescent device.

In the organic electroluminescent device of the present invention, a transmission distribution of carriers is adjusted by properly setting the organic function layer, thereby improving a luminous efficiency of the organic electroluminescent device and facilitating improvement of a service life of the organic electroluminescent device. Meanwhile, a distribution of the carriers in the OLED device is adjusted by selecting materials of organic layers such as the transport layer and the light emitting layer and providing the blocking layer, so that quenching of the carriers at the electrode and quenching of carrier pairs and excitons are avoided.

### BRIEF DESCRIPTION OF THE DRAWINGS

FIG. 1 is a schematic diagram of a structure of an organic electroluminescent device in the prior art;

FIG. 2 is a schematic diagram of a structure of an organic electroluminescent device in a first embodiment of the present invention;

FIG. 3 is a schematic diagram of a structure of an organic electroluminescent device in a second embodiment of the present invention;

FIGS. 4, 5 and 6 are schematic diagrams of structures of an organic electroluminescent device in a third embodiment of the present invention;

FIGS. 7 and 8 are schematic diagrams of structures of an organic electroluminescent device in a fourth embodiment of the present invention;

FIGS. 9 and 10 are schematic diagrams of structures of an organic electroluminescent device in a fifth embodiment of the present invention; and

FIG. 11 is a schematic diagram of a structure of an organic electroluminescent device in a sixth embodiment of the present invention.

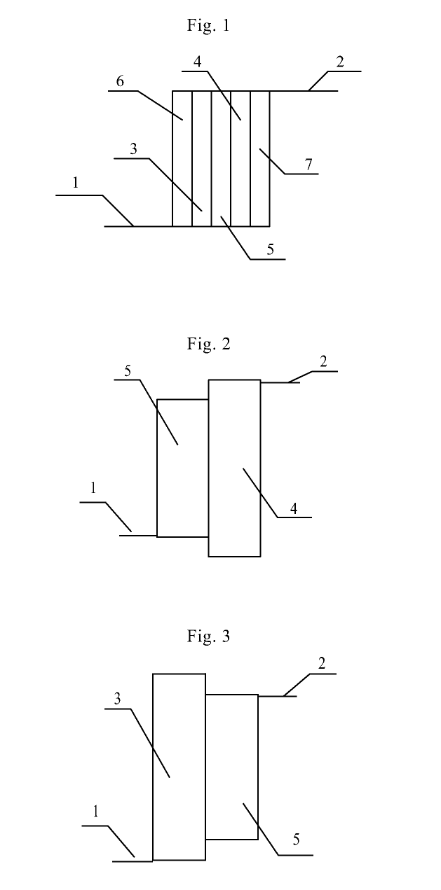

### DESCRIPTION OF THE PREFERRED EMBODIMENT

To make those skilled in the art better understand the technical solutions of the present invention, the present invention will be described as below in details in conjunction with the accompanying drawings and specific implementations.

An organic electroluminescent device according to the embodiment of present invention comprises a substrate, an anode layer, a cathode layer and an organic function layer provided between the anode layer and the cathode layer, the organic function layer comprises a light emitting layer. An injection barrier from the anode layer to the organic function layer and an injection barrier from the cathode layer to the organic function layer are both not larger than 1 ev. The light emitting layer comprises a hole carrier transport region at a side of the anode layer, an electron carrier transport region at a side of the cathode layer, and a light emitting region provided between the hole carrier transport region and the electron carrier transport region, there is no barrier for the hole carriers from the hole carrier transport region to the light emitting region and there is no barrier for the electron carriers from the electron carrier transport region to the light emitting region. Meanwhile, a distribution of the carriers in the organic light emitting device is adjusted by selecting materials of organic layers such as the transport layer and the light emitting layer and providing a blocking layer, so that quenching of the carriers at the electrode and quenching of carrier pairs and excitons are avoided.

In the device, the anode layer, which serves as a connection layer of the organic electroluminescent device for forward voltage, has good electrical conductivity, visible light transparency and high work function. The anode layer is made of inorganic metal oxide (e.g., indium tin oxide (ITO), zinc oxide (ZnO), etc.) or metal material with high work function (e.g., gold, copper, silver, platinum, etc.).

In the device, the cathode layer, which serves as a connection layer of the electroluminescent device for negative voltage, has good electrical conductivity and low work function. The cathode layer is generally made of metal material with low work function, such as lithium, magnesium, calcium, strontium, aluminum, indium etc. or alloys of said metal with copper, gold or silver, or made of a thin layer of buffer insulation layer (e.g., LiF, CsCO₃, etc.) and said metal or alloys.

In the device, the light emitting layer may be made of undoped fluorescent organic material consisting of light emitting material and having a hole carrier transport capability not lower than an electron carrier transport capability, or may be made of organic material doped with fluorescent material and consisting of fluorescent dopant and host material, or may be made of organic material doped with phosphorescent material and consisting of phosphorescent dopant and host material.

In the device, the light emitting layer may be made of undoped fluorescent organic material consisting of light emitting material and having an electron carrier transport capability not lower than a hole carrier transport capability, or may be made of organic material doped with fluorescent material and consisting of fluorescent dopant and host material, or may be made of organic material doped with phosphorescent material and consisting of phosphorescent dopant and host material.

It should be noted that, on the basis of values of HOMO and LUMO (lowest unoccupied molecular orbital) and position of vacuum level, as shown in FIGS. 2 through 11, the level with the larger absolute value of energy is located at the lower position, and the level with the smaller absolute value of energy is located at the higher position. In order to better reflect situations of barriers between layers, in FIGS. 2 through 11, the anode layer 1 and the cathode layer 2 are not illustrated as specific layer structures and high and low positions thereof are only illustrated according to relationship of work functions.

Hereinafter, several cases of the present invention will be described by specific embodiments.

### First Embodiment

As shown in FIG. 2, this embodiment provides an organic electroluminescent device that comprises an anode layer 1, a cathode layer 2 and an organic function layer provided between the anode layer 1 and the cathode layer 2. In the embodiment, a light emitting layer 5 and an electron transport layer 4 provided between the light emitting layer 5 and the cathode layer 2 are provided in the organic function layer, and a LUMO energy level position of the electron transport layer 4 is higher than that of the light emitting layer 5 by 0˜1 ev, the light emitting layer 5 has a hole carrier transport capability not lower than an electron carrier transport capability.

In the embodiment, the light emitting layer 5 itself has a good hole carrier transport capability, that is, the light emitting layer 5 has a good transport capability for the hole carriers from the anode layer 1, especially when the light emitting layer 5 has the hole carrier transport capability much higher than the electron carrier transport capability. The light emitting layer 5 is generally made of undoped fluorescent organic material (luminescent material having the hole carrier transport capability higher than the electron carrier transport capability), the luminescent material having the hole carrier transport capability may utilize NPB (LUMO and HOMO energy levels of which are 2.4 ev and 5.4 ev, respectively) or DPVBi (LUMO and HOMO energy levels of which are 2.8 ev and 5.9 ev, respectively). Meanwhile, since the LUMO energy level position of the electron transport layer 4 is higher than that of the light emitting layer 5, the electron carriers from the cathode layer 2 are easy to be transported to the light emitting layer 5, and the hole carriers and the electron carriers are recombined to emit light in the light emitting layer 5. The material of the electron transport layer 4 may be TPBi (LUMO and HOMO energy levels of which are 2.7 ev and 6.2 ev, respectively). The work function of ITO anode subjected to a chlorine treatment may be adjusted from 5.6 ev to 6.15 ev, and the work function of calcium (Ca) is 2.87 ev.

In the embodiment, since the light emitting layer 5 has a good transport characteristic for the hole carriers, and the LUMO energy level position of the electron transport layer 4 is higher than that of the light emitting layer 5, the electron carriers are easy to be transported to the light emitting layer 5. In this case, there is no significant barrier during entire transport of the hole carriers and the electron carriers, and thus the luminous efficiency of the electroluminescent device may be improved.

Preferably, the HOMO energy level position of the electron transport layer 4 is lower than that of the light emitting layer 5 by 0˜1 ev. In this case, the electron carriers which are not recombined are blocked from moving to the anode layer 1, and the quenching at the electrode is avoided.

In the embodiment, preferably, the organic function layer may further comprise at least one electron blocking layer for blocking the non-recombined electron carriers from moving to the anode layer 1. Specifically, taking the light emitting layer 5 in which one electron blocking layer is provided as an example, the electron blocking layer is very thin, and the thickness is preferably ranged from 1 nm to 10 nm. When the electron carriers are moved to the light emitting layer 5, the electron carriers are recombined with the hole carriers injected from the anode layer 1 in the light emitting layer 5, and the non-recombined electron carriers are recombined with the hole carriers at a portion of the light emitting layer 5 close to the anode layer 1 by the electron blocking layer. The distribution of the electron carriers in the light emitting layer is adjusted by adjusting the thickness of the electron blocking layer and setting the distribution, thereby facilitating the recombination of the electron carriers and the hole carriers, preventing redundant electron carriers from moving to the anode layer 1 and avoiding the quenching at the anode layer 1, and adjusting a transmission distribution of the carriers, so that the luminous efficiency of the organic electroluminescent device is improved.

Fabricating materials and thicknesses of respective layers of a specific organic electroluminescent device in the embodiment are as follows.

ITO-Cl/DPVBi (60 nm)/TPBi (60 nm)/Ca (20 nm)/Al (100 nm), that is, the anode layer 1 is made of indium tin oxide subjected to a chlorine treatment; the light emitting layer 5 is made of DPVBi, the thickness of which is 60 nm; the electron transport layer 4 is made of TPBi, the thickness of which is 60 nm; the cathode layer 2 is made of a composite structure of calcium (Ca) and aluminum (Al), the thicknesses of which are 20 nm and 100 nm, respectively.

Fabricating materials and thicknesses of respective layers of another specific organic electroluminescent device in the embodiment are as follows.

ITO-Cl/DPVBi (10 nm)/TCTA (5 nm)/DPVBi (50 nm)/TPBi (60 nm)/Ca (20 nm)/Al (100 nm), that is, the anode layer 1 is made of indium tin oxide subjected to a chlorine treatment; the light emitting layer 5 is made of DPVBi, the thickness of which is 60 nm; the electron blocking layer is inserted into the light emitting layer 5 and is made of TCTA (LUMO and HOMO energy levels of which are 2.7 ev and 5.9 ev, respectively), the thickness of which is 5 nm; the electron transport layer 4 is made of TPBi, the thickness of which is 60 nm; the cathode layer 2 is made of a composite structure of calcium (Ca) and aluminum (Al), the thicknesses of which are 20 nm and 100 nm, respectively.

### Second Embodiment

As shown in FIG. 3, this embodiment provides an organic electroluminescent device that comprises an anode layer 1, a cathode layer 2 and an organic function layer provided between the anode layer 1 and the cathode layer 2. In the embodiment, a light emitting layer 5 and a hole transport layer 3 provided between the light emitting layer 5 and the anode layer 1 are provided in the organic function layer, and a HOMO energy level position of the hole transport layer 3 is lower than that of the light emitting layer 5 by 0˜1 ev, the light emitting layer 5 has an electron carrier transport capability not lower than a hole carrier transport capability.

In the embodiment, the light emitting layer 5 itself has a good electron carrier transport capability, that is, the electron carriers from the cathode layer 2 are easy to be transported to the light emitting layer 5, especially when the light emitting layer has the electron carrier transport capability much higher than the hole carrier transport capability. The material of the light emitting layer 5 having a good electron carrier transport capability may be Liq (LUMO and HOMO energy levels of which are 2.0 ev and 4.65 ev, respectively); the material for the hole carrier transport may be NPB (LUMO and HOMO energy levels of which are 2.4 ev and 5.4 ev, respectively) or TCTA (LUMO and HOMO energy levels of which are 2.7 ev and 5.9 ev, respectively). Meanwhile, since the HOMO energy level position of the hole transport layer 3 is lower than that of the light emitting layer 5 by 0˜1 ev, the hole carriers are easy to be transported to the light emitting layer 5, and the hole carriers and the electron carriers are recombined to emit light in the light emitting layer 5. In this case, there is no significant barrier during entire transport of the hole carriers and the electron carriers, and thus the luminous efficiency of the electroluminescent device may be improved.

Preferably, the LUMO energy level position of the hole transport layer 3 is higher than that of the light emitting layer 5 by 0˜1 ev. In this case, the hole carriers which are not recombined are blocked from moving to the cathode layer 2, and the quenching at the electrode is avoided.

In the embodiment, preferably, the light emitting layer 5 may further comprise at least one hole blocking layer for blocking the non-recombined hole carriers from moving to the cathode layer 2. Specifically, taking the light emitting layer 5 in which one hole blocking layer is provided as an example, the hole blocking layer is very thin, and the thickness is preferably ranged from 1 nm to 10 nm. When the hole carriers are moved to the light emitting layer 5, the hole carriers are recombined with the electron carriers at a portion of the light emitting layer 5 close to the anode layer 1, and then the non-recombined hole carriers are recombined with the electron carriers at a portion of the light emitting layer 5 close to the cathode layer 2 by the hole blocking layer. In this case, the function of the hole blocking layer facilitates the recombination of the hole carriers and the electron carriers, thereby preventing redundant hole carriers from moving to the cathode layer 2 and avoiding the quenching at the cathode layer 2, and adjusting a transmission distribution of the carriers, so that the luminous efficiency of the organic electroluminescent device is improved.

Fabricating materials and thicknesses of respective layers of a specific organic electroluminescent device in the embodiment are as follows. ITO-Cl/TCTA (60 nm)/Liq:DCJTB (2%, 60 nm)/Ca (20 nm)/Al (100 nm), that is, the anode layer 1 is made of indium tin oxide subjected to a chlorine treatment; the hole transport layer 3 is made of TCTA, the thickness of which is 60 nm; the light emitting layer 5 is made of red dye DCJTB doped Liq, the doping concentration is 2% and the total thickness of the light emitting layer is 60 nm; the cathode layer 2 is made of a composite structure of calcium (Ca) and aluminum (Al), the thicknesses of which are 20 nm and 100 nm, respectively.

### Third Embodiment

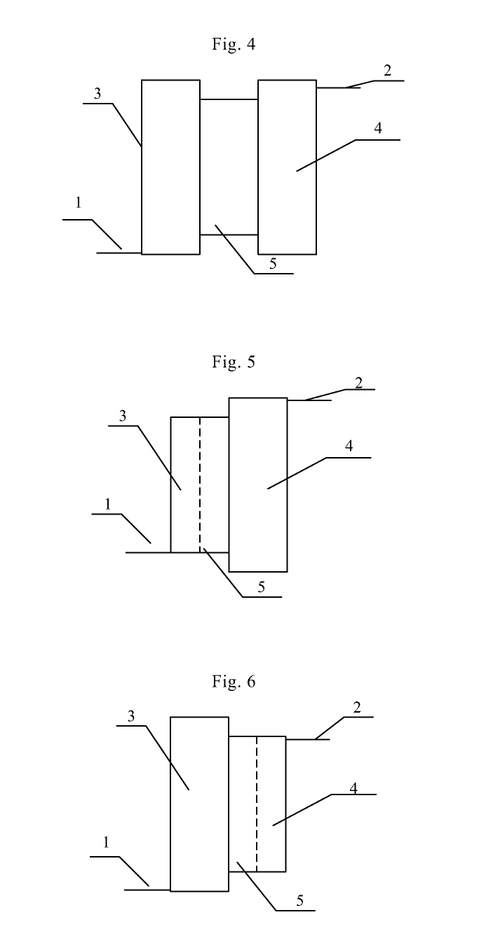

As shown in FIG. 4, this embodiment provides an organic electroluminescent device that comprises an anode layer 1, a cathode layer 2 and an organic function layer provided between the anode layer 1 and the cathode layer 2, the organic function layer comprises a light emitting layer 5, a hole transport layer 3 and an electron transport layer 4, the hole transport layer 3 is provided between the light emitting layer 5 and the anode layer 1, and the electron transport layer 4 is provided the cathode layer 2 and the light emitting layer 5. In the device, a HOMO energy level position of the hole transport layer 3 is lower than that of the light emitting layer 5 by 0˜1 ev, and a LUMO energy level position of the electron transport layer 4 is higher than that of the light emitting layer 5 by 0˜1 ev.

In the embodiment, the material of the hole transport layer 3 may be TCTA (LUMO and HOMO energy levels of which are 2.7 ev and 5.9 ev, respectively); the material of the light emitting layer 5 may be TCTA (LUMO and HOMO energy levels of which are 2.7 ev and 5.9 ev, respectively), CBP (LUMO and HOMO energy levels of which are 2.9 ev and 5.6 ev, respectively), TPBi (LUMO and HOMO energy levels of which are 2.7 ev and 6.2 ev, respectively) or TAZ (LUMO and HOMO energy levels of which are 2.6 ev and 6.6 ev, respectively), the dopant of the light emitting layer 5 may be fluorescent material or phosphorescent material, such as C-545, Ir(ppy)₃, etc.; and the material for the electron carrier transport may be TAZ (LUMO and HOMO energy levels of which are 2.6 ev and 6.6 ev, respectively).

In the organic electroluminescent device according to the embodiment, since the HOMO energy level position of the hole transport layer 3 is lower than that of the light emitting layer 5 by 0˜1 ev, and the LUMO energy level position of the electron transport layer 4 is higher than that of the light emitting layer 5 by 0˜1 ev, the hole carriers and the electron carriers are both easy to be injected into the light emitting layer 5, so that the hole carriers and the electron carriers are prevented from being aggregated to generate transport barriers, and the luminous efficiency of the organic electroluminescent device is improved.

Fabricating materials and thicknesses of respective layers of a specific organic electroluminescent device in the embodiment are as follows.

ITO-Cl/TCTA (30 nm)/CBP:Ir(ppy)₃ (6%, 30 nm)/TPBi (30 nm)/Ca (20 nm)/Al (100 nm), that is, the material of the anode layer 1 is indium tin oxide (ITO); the hole transport layer 3 is made of TCTA, the thickness of which is 30 nm; the light emitting layer 5 is made of CBP, the dopant is Ir(ppy)₃, the doping concentration the dopant is 6%, and the thickness of the light emitting layer is 30 nm; the electron transport layer 4 is made of TPBi, the thickness of which is 30 nm; the cathode layer 2 is made of a composite structure of calcium (Ca) and aluminum (Al), the thicknesses of which are 20 nm and 100 nm, respectively.

As shown in FIG. 5, as an aspect of the embodiment, the light emitting layer 5 may be made of undoped fluorescent organic material consisting of light emitting material and having a hole carrier transport capability, the electron transport layer 4 is provided between the cathode layer 2 and the light emitting layer 5, and the LUMO energy level position of the electron transport layer 4 is higher than that of the light emitting layer 5 by 0˜1 ev. The light emitting layer 5 may also be made of organic material doped with fluorescent material and consisting of fluorescent dopant and host material, or may be made of organic material doped with phosphorescent material and consisting of phosphorescent dopant and host material.

In the embodiment, since the LUMO energy level position of the electron transport layer 4 is higher than that of the light emitting layer 5, the electron carriers may be easy to be injected into the light emitting layer 5. Meanwhile, since the material of the hole transport layer 3 is the same as that of the light emitting layer 5, the light emitting layer 5 has a good transport characteristic for the hole carriers, and the hole carriers may be recombined with the electron carriers well in the light emitting layer 5. Such structure reduces the quenching of exciton caused by the aggregation of the carriers and improves the efficiency of the device. Since the light emitting layer 5 has the same material as the hole transport layer 3, the fabricating process is also simplified.

In the device, the organic function layer further comprises an electron blocking layer, the structure of the electron blocking layer and the principle of blocking the electrons are similar to those of the electron blocking layer in the first embodiment, and the description thereto is omitted herein. The material of the electron blocking layer may have the same range as selection of material of the hole transport layer (the light emitting layer 5).

In the device, the material of the light emitting layer 5 (the hole transport layer 3/the electron blocking layer) may be TCTA (LUMO and HOMO energy levels of which are 2.7 ev and 5.9 ev, respectively). When the light emitting layer 5 is doped with a dopant, the dopant may be fluorescent material or phosphorescent material, such as C545, Ir(ppy)₃, etc., and the material of the electron transport layer 4 may be TAZ (LUMO and HOMO energy levels of which are 2.6 ev and 6.6 ev, respectively).

Fabricating materials and thicknesses of respective layers of a specific organic electroluminescent device in the embodiment are as follows.

ITO-Cl/TCTA (30 nm)/TCTA:Ir(ppy)₃ (30 nm)/TPBi (30 nm)/Ca (20 nm)/Al (100 nm), that is, the anode layer 1 is made of indium tin oxide subjected to a chlorine treatment; the hole transport layer 3 is made of TCTA, the thickness of which is 30 nm; the light emitting layer 5 is made of TCTA, the dopant is Ir(ppy)₃, and the thickness is 30 nm; the electron transport layer 4 is made of TPBi, the thickness of which is 30 nm; the cathode layer 2 is made of a composite structure of calcium (Ca) and aluminum (Al), the thicknesses of which are 20 nm and 100 nm, respectively.

As shown in FIG. 6, as another aspect of the embodiment, the material of the electron transport layer 4 is the same as that of the light emitting layer 5. The hole transport layer 3 is provided between the anode layer 1 and the light emitting layer 5, the HOMO energy level position of the hole transport layer 3 is lower than that of the light emitting layer 5 by 0˜1 ev.

In the embodiment, since the HOMO energy level position of the hole transport layer 3 is lower than that of the light emitting layer 5, the hole carriers is easy to be transported to the light emitting layer 5. The light emitting layer 5 is made of undoped fluorescent organic material consisting of light emitting material and having an electron carrier transport capability. The light emitting layer 5 has a good transport characteristic for the electron carriers, and the hole carriers may be better recombined with the electron carriers in the light emitting layer 5 to emit light, so that the quenching of exciton caused by the aggregation of the carriers is reduced, and the efficiency of the device may be improved. Since the light emitting layer 5 has the same material as the electron transport layer 4, the fabricating process is also simplified. The light emitting layer 5 may also be made of organic material doped with fluorescent material and consisting of fluorescent dopant and host material, or may be made of organic material doped with phosphorescent material and consisting of phosphorescent dopant and host material.

Preferably, a hole blocking layer is further provided in the light emitting layer 5, the structure and the property of the hole blocking layer are the same as those of the hole blocking layer in the second embodiment, and the description thereto is omitted herein.

Fabricating materials and thicknesses of respective layers of a specific organic electroluminescent device in the embodiment are as follows.

ITO-Cl/TCTA (30 nm)/TPBi:Ir(ppy)₃ (30 nm)/TPBi (30 nm)/Ca (20 nm)/Al (100 nm), that is, the anode layer 1 is made of indium tin oxide; the hole transport layer 3 is made of TCTA, the thickness of which is 30 nm; the light emitting layer 5 is made of TPBi, the dopant is Ir(ppy)₃, and the thickness is 30 nm; the electron transport layer 4 is made of TPBi, the thickness of which is 30 nm; the cathode layer 2 is made of composite structure of calcium (Ca) and aluminum (Al), the thicknesses of which are 20 nm and 100 nm, respectively.

### Fourth Embodiment

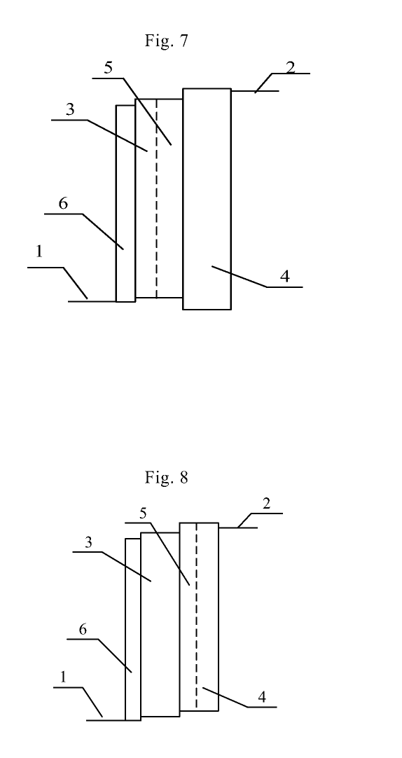

As shown in FIGS. 7 and 8, this embodiment provides an organic electroluminescent device comprising the structure of the organic electroluminescent device of any one of the first through third embodiments, the organic function layer of which further comprises a hole injection layer 6. The hole injection layer 6 is provided between the anode layer 1 and the hole transport layer 3/the light emitting layer 5 of the organic electroluminescent device, so as to improve injection efficiency of the hole carriers or improve interface condition of the anode electrode.

Specifically, as shown in FIGS. 7 and 8, the hole injection layer 6 is provided between the anode layer 1 and the hole transport layer 3. The structure of the organic electroluminescent device from the anode layer 1 to the cathode layer 2 is: the anode layer 1, the hole injection layer 6, the hole transport layer 3, the light emitting layer 5, the electron transport layer 4 and the cathode layer 2. The hole transport layer 3 and the light emitting layer 5 may be made of the same material, or the material of the light emitting layer 5 has a good transport characteristic for the hole carriers (i.e., the light emitting layer 5 and the hole transport layer 3 are integrated as a whole), resulting in the structure shown in FIG. 7. Of course, the hole transport layer 3 and the light emitting layer 5 may be made of different materials, resulting in the structure shown in FIG. 8. In short, the hole injection layer 6 is added in the structure of FIG. 5 or 6 in the third embodiment. The addition of the hole injection layer 6 may facilitate the injection of the hole carriers from the anode layer 1 into the light emitting layer 5, and may improve the interface condition of the anode electrode as better injection of the hole carriers.

The hole injection layer 6 is added in the embodiment, which facilitates the injection of the holes into the hole transport layer 3, so that the holes are better injected into the light emitting layer 5. The material of the hole injection layer 6 is p-doped hole injection material, the dopant of which is F4-TCNQ. In this case, the materials of the anode layer 1 and the cathode layer 2 are generally selected as normal metal materials, which may solve the problem of limitation of selection for kinds of the material of the anode layer 1 with high work function. Meanwhile, p-doped hole transport layer 3 makes the interface between the metal and the organic become an ohmic contact, so that the injection barrier for the hole carriers are significantly reduced, and the quenching of carriers and exciton is reduced.

### Fifth Embodiment

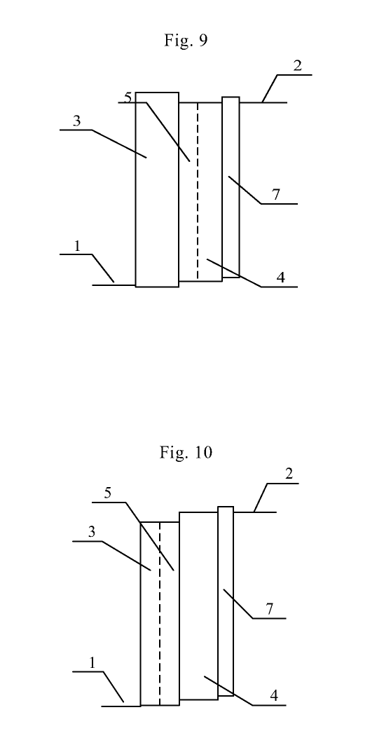

As shown in FIGS. 9 and 10, this embodiment provides an organic electroluminescent device comprising the organic function layer of any one of the first through third embodiments, the organic function layer further comprises an electron injection layer 7. The electron injection layer 7 is provided between the cathode layer 2 and the electron transport layer 4/the light emitting layer 5 of the organic electroluminescent device, so as to improve an injection efficiency of the electron carriers or improve an interface condition of the cathode electrode.

Specifically, as shown in FIGS. 9 and 10, the electron injection layer 7 is provided between the cathode layer 2 and the electron transport layer 4. The structure of the organic electroluminescent device from the anode layer 1 to the cathode layer 2 is: the anode layer 1, the hole transport layer 3, the light emitting layer 5, the electron transport layer 4, the electron injection layer 7 and the cathode layer 2. The electron transport layer 4 and the light emitting layer 5 may be made of the same material, or the material of the light emitting layer 5 has a good transport characteristic for the electron carriers (i.e., the light emitting layer 5 and the electron transport layer 4 are integrated as a whole), resulting in the structure shown in FIG. 9. Of course, the electron transport layer 4 and the light emitting layer 5 may be made of different materials, resulting in the structure shown in FIG. 10. In short, the electron injection layer 7 is added in the structure of FIG. 5 or 6 in the third embodiment. The addition of the electron injection layer 7 may facilitate the injection of the electron carriers from the cathode layer 2 into the light emitting layer 5, and may improve the interface condition of the cathode electrode as better injection of the electron carriers.

In the device, the material of the electron injection layer 7 is n-doped electron injection material, the dopant of which is Ce or Li. In the embodiment, the electron injection layer 7 is added, so that the injection barrier of the organic electroluminescent device is reduced, which facilitates injection of the electron carriers.

### Six Embodiment

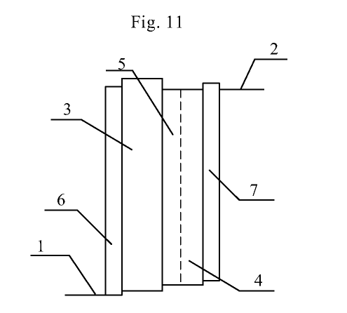

As shown in FIG. 11, this embodiment provides an organic electroluminescent device comprising the structure of the organic electroluminescent device of any one of the first through third embodiments, the organic function layer further comprises a hole injection layer 6 and an electron injection layer 7, so as to improve injection efficiencies of the hole carriers and the electron carriers, thereby improving the luminous efficiency of the organic electroluminescent device.

In the device, the hole injection layer 6 is the same as the hole injection layer 6 in the fourth embodiment, the electron injection layer 7 is the same as the electron injection layer 7 in the fifth embodiment, and the description thereto is omitted herein.

The present invention further provides a display device that comprises the above organic electroluminescent device.

It should be understood that, the implementations described above are merely exemplary implementations for describing the principle of the present invention, but the present invention is not limited thereto. For the persons skilled in the art, various variations and improvements may be made without departing from the spirit and essence of the present invention, and these variations and improvements shall be deemed as falling within the protection scope of the present invention.

1-20. (canceled)

21. An organic electroluminescent device, comprising an anode layer, a cathode layer and an organic function layer provided between the anode layer and the cathode layer, the organic function layer comprising a light emitting layer, wherein an injection barrier from the anode layer to the organic function layer and an injection barrier from the cathode layer to the organic function layer are both not larger than 1 ev; and
the light emitting layer comprises a hole carrier transport region at a side of the anode layer, an electron carrier transport region at a side of the cathode layer, and a light emitting region provided between the hole carrier transport region and the electron carrier transport region, wherein there is no barrier for the hole carriers from the hole carrier transport region to the light emitting region and there is no barrier for the electron carriers from the electron carrier transport region to the light emitting region.

22. The organic electroluminescent device according to claim 21, wherein the light emitting layer is made of undoped fluorescent organic material consisting of light emitting material and having a hole carrier transport capability not lower than an electron carrier transport capability, or the light emitting layer is made of organic material doped with fluorescent material, consisting of fluorescent dopant and host material and having a hole carrier transport capability not lower than an electron carrier transport capability, or the light emitting layer is made of organic material doped with phosphorescent material, consisting of phosphorescent dopant and host material and having a hole carrier transport capability not lower than an electron carrier transport capability.

23. The organic electroluminescent device according to claim 21, wherein the light emitting layer is made of undoped fluorescent organic material consisting of light emitting material and having an electron carrier transport capability not lower than a hole carrier transport capability, or the light emitting layer is made of organic material doped with fluorescent material, consisting of fluorescent dopant and host material and having an electron carrier transport capability not lower than a hole carrier transport capability, or the light emitting layer is made of organic material doped with phosphorescent material, consisting of phosphorescent dopant and host material and having an electron carrier transport capability not lower than a hole carrier transport capability.

24. The organic electroluminescent device according to claim 21, wherein the organic function layer further comprises an electron transport layer provided between the light emitting layer and the cathode layer, a LUMO energy level position of the electron transport layer is higher than that of the light emitting layer by 0˜1 ev, and the light emitting layer has a hole carrier transport capability not lower than an electron carrier transport capability.

25. The organic electroluminescent device according to claim 24, wherein a HOMO energy level position of the electron transport layer is lower than that of the light emitting layer by 0˜1 ev.

26. The organic electroluminescent device according to claim 25, wherein the organic function layer further comprises an electron blocking layer for blocking non-recombined electron carriers from moving to the anode layer.

27. The organic electroluminescent device according to claim 26, wherein a thickness of the electron blocking layer is ranged from 1 nm to 10 nm.

28. The organic electroluminescent device according to claim 26, wherein the non-recombined electron carriers are recombined with the hole carriers at a portion of the light emitting layer close to the anode layer by the electron blocking layer.

29. The organic electroluminescent device according to claim 21, wherein the organic function layer further comprises a hole transport layer provided between the anode layer and the light emitting layer, a HOMO energy level position of the hole transport layer is lower than that of the light emitting layer by 0˜1 ev, and the light emitting layer has an electron carrier transport capability not lower than a hole carrier transport capability.

30. The organic electroluminescent device according to claim 29, wherein a LUMO energy level position of the hole transport layer is higher than that of the light emitting layer by 0˜1 ev.

31. The organic electroluminescent device according to claim 29, wherein the organic function layer further comprises a hole blocking layer for blocking non-recombined hole carriers from moving to the cathode layer.

32. The organic electroluminescent device according to claim 31, wherein a thickness of the hole blocking layer is ranged from 1 nm to 10 nm.

33. The organic electroluminescent device according to claim 31, wherein the non-recombined hole carriers are recombined with the electron carriers at a portion of the light emitting layer close to the cathode layer by the hole blocking layer.

34. The organic electroluminescent device according to claim 21, wherein the organic function layer further comprises a hole transport layer provided between the anode layer and the light emitting layer and an electron transport layer provided between the cathode layer and the light emitting layer, a HOMO energy level position of the hole transport layer is lower than that of the light emitting layer by 0˜1 ev, and a LUMO energy level position of the electron transport layer is higher than that of the light emitting layer by 0˜1 ev.

35. The organic electroluminescent device according to claim 34, wherein the light emitting layer is made of organic material consisting of light emitting material and having a hole carrier transport capability or made of organic material consisting of light emitting material and having an electron carrier transport capability.

36. The organic electroluminescent device according to claim 21, wherein the organic function layer further comprises a hole injection layer that is provided between the anode layer and the hole transport layer of the organic electroluminescent device.

37. The organic electroluminescent device according to claim 36, wherein the material of the hole injection layer is p-doped hole injection material, the dopant material of which is F4-TCNQ.

38. The organic electroluminescent device according to claim 21, wherein the organic function layer further comprises an electron injection layer that is provided between the cathode layer and the electron transport layer of the organic electroluminescent device.

39. The organic electroluminescent device according to claim 38, wherein the material of the electron injection layer is n-doped electron injection material, the dopant material of which is Ce or Li.

40. A display device, comprising the organic electroluminescent device according to claim 21.
